(19) United States
(12) Patent Application Publication
(10) Pub. No.: US 2008/0087492 A1
(43) Pub. Date: Apr. 17, 2008

(54) Fire-resistant barrier

(76) Inventors: David H. Cox, Simi Valley, CA (US); Rick Kamlet, Valencia, CA (US)

Correspondence Address: THE ECLIPSE GROUP, 10605 BALBOA BLVD., SUITE 300, GRANADA HILLS, CA, 91344, US

(21) Appl. No.: 11/580,684

(22) Filed: Oct. 12, 2006

(51) Int. Cl. H05K 5/00

(52) U.S. Cl. 181/150

(57) ABSTRACT

Fire-resistant shroud (“Fire Shroud”) for a barrier surface-mountable electromagnetic device, including a synthetic vitreous fiber body having a cavity configured to the shape of a portion of the electromagnetic device. Barrier surface-mountable loudspeaker system, including a barrier surface-mountable loudspeaker having a back-can including a sound-producing element; and a synthetic vitreous fiber body having a cavity configured to the shape of a barrier surface-mountable loudspeaker back-can. Method of installing a barrier surface-mountable electromagnetic device in a barrier surface of an interior space.

### BACKGROUND OF THE INVENTION

1. Field of the Invention

This invention relates to fire-resistant barriers for electromagnetic devices, such as loudspeakers, that are mountable in barrier surfaces of interior spaces.

2. Related Art

Fire prevention for interior spaces, including interior spaces of commercial and residential buildings and in transportation vehicles including aircraft, trains, boats, automobiles and trucks as examples, is an important component of measures taken to prevent fatalities. Extensive laws and regulations, industry codes, and testing schemes are directed to such fire prevention, such as standards issued by Underwriters' Laboratories in the United States and Canada, ASTM International, and the National Fire Protection Association. Barrier surfaces of interior spaces, including surfaces of floors, walls and ceilings in buildings and in transportation vehicles, are subjects of these types of laws, regulations, industry codes and testing schemes. Efforts are often made to require that such barrier surfaces are fabricated utilizing fire-proof or fire-resistant materials whenever practical. Ceilings of interior building spaces, as an example, are often required to be formed of such materials.

However, barrier surfaces of such interior spaces are commonly breached by myriad fittings, conduits, and devices including electromagnetic devices that are typically mounted in apertures formed in these barrier surfaces. Whenever a breach is made in a barrier surface of an interior space that serves as a fire-proof or fire-resistant barrier, the effectiveness of the barrier may be compromised. In addition to facilitating penetration of fire through the barrier surface, such breaches may also permit smoke penetration. In many cases, fatalities resulting from fires occurring within interior spaces of buildings and transportation vehicles are caused by smoke inhalation rather than by the fire itself. Combustion of many typical building materials as well as furnishings such as carpeting as an example, often results in the generation of highly toxic smoke. Inhalation of this smoke results in asphyxiation including catastrophic lung damage, poisoning, suffocation, and ultimately death.

Breaching of a barrier surface such as a surface of a floor, wall or ceiling of an interior space to install an electromagnetic device into such a barrier surface often requires that specific standards are then met to reduce the potential for fire or smoke to pass through the breach. One type of such electromagnetic devices is barrier surface-mountable loudspeakers. In general, only the sound-emission interface of a barrier surface-mountable loudspeaker, which may as an example include a grille positioned over a sound-producing element, needs to be exposed to a building interior space for the loudspeaker to be properly functional. Since loudspeakers are often bulky, a common goal for barrier surface-mountable loudspeaker installation is to hide the bulk of the loudspeaker in the barrier. The resulting breach in the barrier surface often requires that measures be taken to reduce the capability of fire and smoke to penetrate the breach and pass through the barrier surface.

While such measures serve critical life-saving purposes, they also add to the material and labor costs in installation of barrier surface-mountable loudspeakers. Given the many different sizes and shapes of barrier surface-mountable loudspeakers that are commercially available, builders and other installers of such loudspeakers often create a custom-built fire-resistant enclosure for such loudspeakers by making a gypsum board box. Formation of a gypsum board box for a barrier surface-mountable loudspeaker generally includes planning out the footprint of the installed loudspeaker, measuring and cutting down gypsum board sheets to appropriately sized panels, and assembling and joining together the panels to form a box reaching over and around the loudspeaker as well as extending to close proximity with the barrier. The gypsum board box may also be reinforced with a frame made of wood or other rigid materials. If the barrier is a suspended ceiling including a tile grid frame, then forming such a box typically involves the added complications of sizing the panels of gypsum board or other fire-resistant panel material to closely adjoin the ceiling tiles, while negotiating around the tile grid frame. The irregularity of some of the resulting panel dimensions that may be required to effectively form such a fire resistant enclosure may significantly add to the fabrication labor demands and consequent expense of the box.

Pre-fabricated fire-resistant enclosures have also been produced to address these problems with installing barrier surface-mountable loudspeakers in suspended ceilings. Some of such pre-fabricated enclosures have included a panel that frames the sound-emission interface of the loudspeaker. The panel is mounted on ceiling rails in the tile grid frame, and additional pre-cut panels are then assembled and joined together reaching around and over the loudspeaker on the panel that frames the loudspeaker, to form a fire-resistant enclosure. Although functional, the components for making these fire resistant enclosures are bulky, complicated, have inflexible dimensions, and require significant assembly and installation labor. Such fire resistant enclosures may further involve pre-mounting of the loudspeaker at a fixed location in the face of the panel that frames the loudspeaker and forms part of the fire-resistant enclosure, effectively limiting the installation design options for the loudspeaker in a given ceiling.

Accordingly, there is a continuing need for new fire-resistant enclosures for barrier surface-mountable electromagnetic devices.

### SUMMARY

In an example of an implementation, a fire-resistant shroud (“Fire Shroud”) is provided for a barrier surface-mountable electromagnetic device. The Fire Shroud includes a synthetic vitreous fiber body having a cavity configured to the shape of a portion of an electromagnetic device. As an example, the electromagnetic device may be a barrier surface-mountable loudspeaker, and the cavity may be configured to the shape of a barrier surface-mountable loudspeaker back-can. As an example, the synthetic vitreous fiber body may include a first synthetic vitreous fiber sheet in the form of a cylinder, the cylinder having first and second cylinder edges respectively defining first and second cylinder ends, and a second synthetic vitreous fiber sheet joined with the first cylinder edge and closing the first cylinder end. In another example, the synthetic vitreous fiber body may include two half-cylinder synthetic vitreous fiber sheets each shaped as a half-cylinder, the two half-cylinders joined together forming a cylinder, the cylinder having first and second cylinder edges respectively defining first and second cylinder ends, and a second synthetic vitreous fiber sheet joined with the first cylinder edge and closing the first cylinder end. As a further example, the synthetic vitreous fiber body may include an integral synthetic vitreous fiber cylinder, the cylinder having first and second cylinder edges respectively defining first and second cylinder ends, and the synthetic vitreous fiber body including a second synthetic vitreous fiber sheet joined with the first cylinder edge and closing the first cylinder end. In an additional example, the synthetic vitreous fiber body may include an integral synthetic vitreous fiber cylinder having an end-cap.

As another example of an implementation, a barrier surface-mountable loudspeaker system is provided, including a barrier surface-mountable loudspeaker having a back-can including a sound-producing element; and a synthetic vitreous fiber body having a cavity configured to the shape of the barrier surface-mountable loudspeaker back-can.

In a further example of an implementation, a method of installing a barrier surface-mountable electromagnetic device in a barrier surface of an interior space is provided, which includes securing the electromagnetic device in an operable position with a portion of the electromagnetic device within a barrier surface; and installing a fire resistant shroud to contain the portion of the electromagnetic device, the fire resistant shroud including a synthetic vitreous fiber body having a cavity configured to the shape of the portion of the electromagnetic device. As an example, the electromagnetic device may be a barrier surface-mountable loudspeaker including a back-can.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE FIGURES

The invention can be better understood with reference to the following figures. The components in the figures are not necessarily to scale, emphasis instead being placed upon illustrating the principles of the invention. Moreover, in the figures, like reference numerals designate corresponding parts throughout the different views.

FIG. 1 is a perspective view showing an example of an implementation of a Fire Shroud, and a barrier surface-mountable loudspeaker on which the Fire Shroud may be installed.

FIG. 2 is a side view, taken on line 2, of the Fire Shroud of FIG. 1.

FIG. 3 is a top view, taken on line 3-3, of the Fire Shroud of FIG. 1.

FIG. 4 is a perspective view of an example of a cylindrical first synthetic vitreous fiber sheet, and a second synthetic vitreous fiber sheet, in spaced apart alignment for being joined together to form an example of the Fire Shroud of FIG. 1.

FIG. 5 is a perspective view showing the Fire Shroud formed in FIG. 4, installed on a barrier surface-mountable loudspeaker.

FIG. 6 is a perspective view showing an example of the Fire Shroud of FIG. 1 installed on a barrier surface-mountable loudspeaker mounted on ceiling rails of a tile grid frame.

FIG. 7 is a cross-sectional side view taken on line 7-7 of an example of a Fire Shroud of FIG. 6 installed on the barrier surface-mountable loudspeaker mounted on ceiling rails of a tile grid frame.

### DETAILED DESCRIPTION

A fire-resistant shroud (“Fire Shroud”) is provided for an electromagnetic device that is mountable with a portion of the electromagnetic device in a barrier surface of an interior space. As an example, the electromagnetic device may be a barrier surface-mountable loudspeaker. In a further example, the barrier surface-mountable loudspeaker may be a ceiling-mountable loudspeaker. The Fire Shroud includes a synthetic vitreous fiber body having a cavity configured to the shape of the portion of the electromagnetic device. As an example, the cavity may be configured to the shape of a barrier surface-mountable loudspeaker back-can. The synthetic vitreous fiber body may, as an example, include a first synthetic vitreous fiber sheet in the form of a cylinder. In an example, the cylinder may have first and second cylinder edges respectively defining first and second cylinder ends. A second synthetic vitreous fiber sheet may, as an example, be joined with the first cylinder edge and may close the first cylinder end.

Much of the ensuing discussion is directed to Fire Shrouds for barrier surface-mountable loudspeakers. However, in a further example, a Fire Shroud may be configured for utilization with another electromagnetic device that may be mountable with a portion of the electromagnetic device in a barrier surface of an interior space. As an example, such an electromagnetic device may be an in-barrier lighting fixture. In an additional example, such an in-barrier lighting fixture may include a cylindrical back-can typically mounted with a cylinder axis oriented at an angle to the barrier surface, such as a right angle. Such an in-barrier lighting fixture may, as another example, include an elongated back-can mounted coplanar to and with a shallow penetration of the barrier surface.

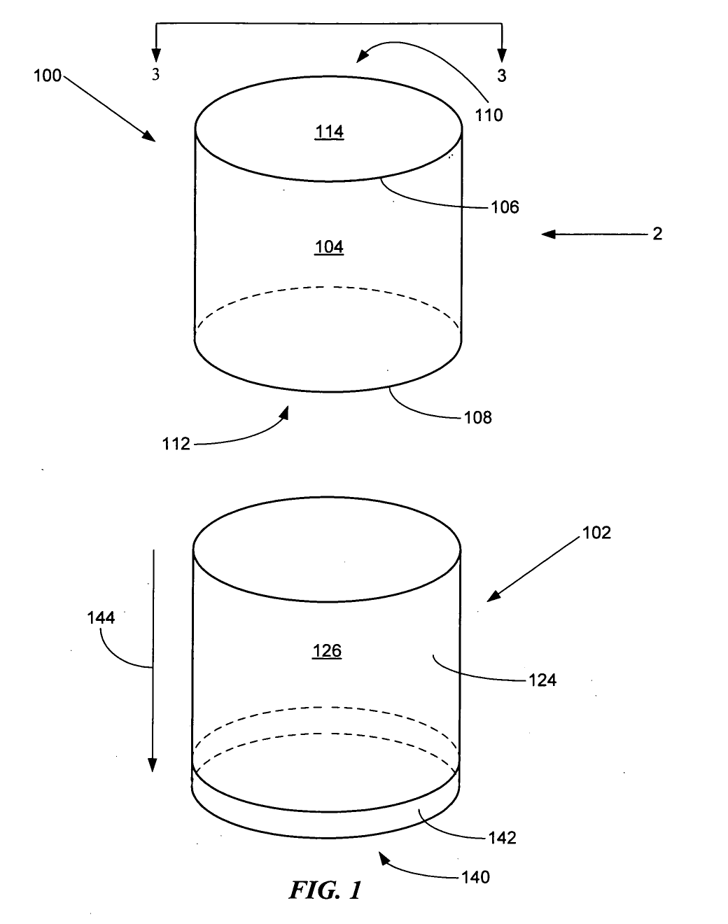

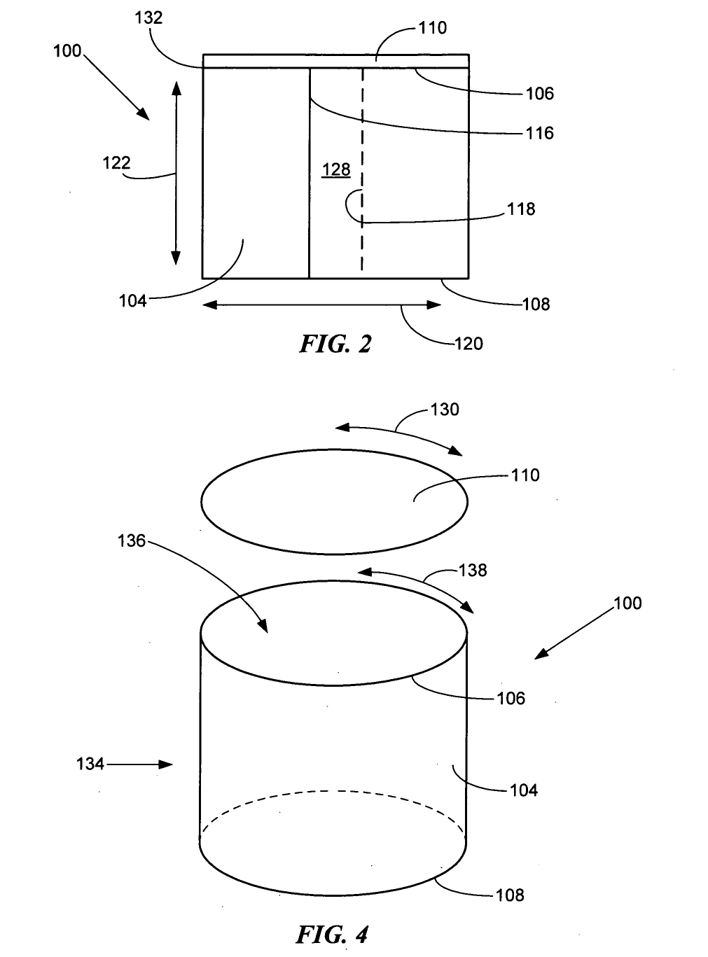

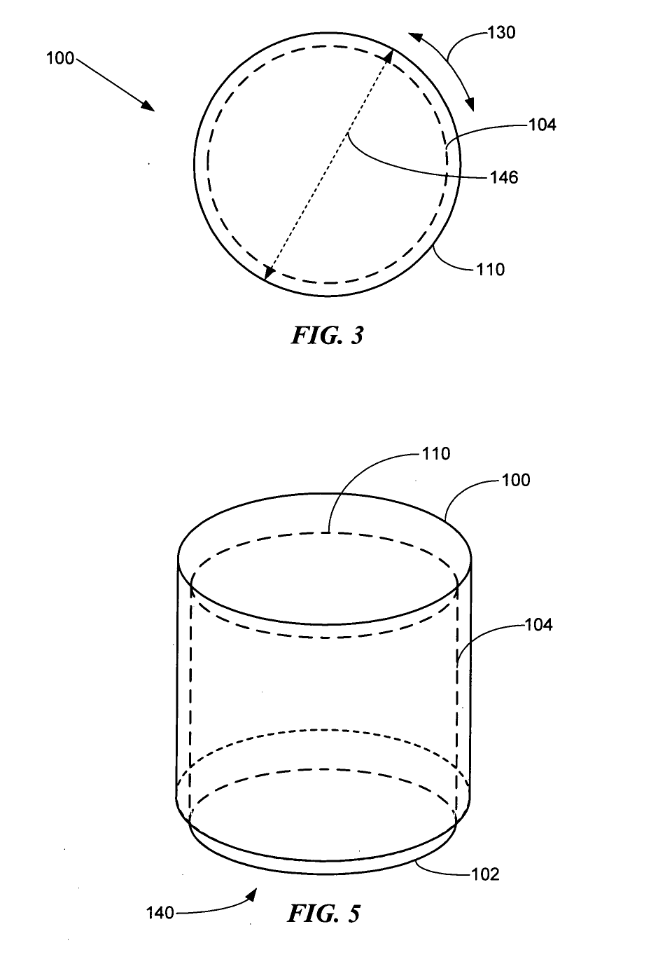

FIG. 1 is a perspective view showing an example of an implementation of a Fire Shroud 100, positioned over a barrier surface-mountable loudspeaker 102 on which the Fire Shroud 100 may be installed. FIG. 2 is a side view, taken on line 2, of the Fire Shroud 100 of FIG. 1. FIG. 3 is a top view, taken on line 3-3, of the Fire Shroud 100 of FIG. 1. The Fire Shroud 100 may, as an example, include a first synthetic vitreous fiber sheet in the form of a cylinder (“cylindrical first synthetic vitreous fiber sheet”) 104, having a first cylinder edge 106 and a second cylinder edge 108. The first cylinder edge 106 may form a first cylinder end 110, and the second cylinder edge 108 may form a second cylinder end 112. The Fire Shroud 100 may further include a second synthetic vitreous fiber sheet 114 joined with the first cylinder edge 106. Together, the cylindrical first synthetic vitreous fiber sheet 104 and the second synthetic vitreous fiber sheet 114 may form a fire-resistant shroud having a cavity configured to the shape of and to contain a barrier surface-mountable loudspeaker back-can.

FIG. 2 illustrates a side view of an example of the Fire Shroud 100. The cylindrical first synthetic vitreous fiber sheet 104 may include a first sheet edge 116 and a second sheet edge 118. The cylindrical first synthetic vitreous fiber sheet 104 may, in an example, be cut to a size having a length in the directions of the arrow 120 and a height in the directions of the arrow 122 that are appropriate for conforming to and containing a cylindrical surface 124 of a back-can 126 of the barrier surface-mountable loudspeaker 102, taking into account any needed overlapping portions of the synthetic vitreous fiber sheet 104 to implement a selected technique for joining together the first sheet edge 116 and the second sheet edge 118 of the synthetic vitreous fiber sheet 104 around the back-can 126. As an example, the first sheet edge 116 and the second sheet edge 118 may be joined together with an overlap region 128. An adhesive composition or an adhesive tape including double-sided adhesive (not shown), as examples, may be interposed between the first sheet edge 116 and the second sheet edge 118 in the overlap region 128. As another example (not shown), the first sheet edge 116 and the second sheet edge 118 may be placed to meet with each other end-to-end, and an adhesive tape may be placed onto both of the sheet edges. As additional examples (not shown), the first sheet edge 116 and the second sheet edge 118 may be joined together by stitching, stapling, or other fasteners. In a further example (not shown), the cylindrical first synthetic vitreous fiber sheet 104 may be formed as an integral tube without a sheet edge. In another example (not shown), the cylindrical first synthetic vitreous fiber sheet may be formed by assembly of two half-cylinder synthetic vitreous fiber sheets each shaped as a half-cylinder having first and second sheet edges. As a further example (not shown), the cylindrical first synthetic vitreous fiber sheet and the second synthetic vitreous fiber sheet may be integrally formed as a cylindrical tube having an integrally-formed end-cap, the end-cap substituting for the second synthetic vitreous fiber sheet.

FIG. 3 shows a top view of the Fire Shroud 100. As an example, the second synthetic vitreous fiber sheet 114 may include a perimeter indicated by the arrow 130 having a generally circular shape. In further examples (not shown), the second synthetic vitreous fiber sheet 114 may have a perimeter indicated by the arrow 130 in another general shape, such as an ellipse, another curved shape, a square, or another polygon.

FIG. 4 is a perspective view of an example of a cylindrical first synthetic vitreous fiber sheet 104, and a second synthetic vitreous fiber sheet 114, in spaced apart alignment for being joined together to form an example of the Fire Shroud 100 of FIG. 1. As an example, an adhesive composition may be placed on the first cylinder edge 106, or on the perimeter indicated by the arrow 130 of the second synthetic vitreous fiber sheet 114, or on both the first cylinder edge 106 and the perimeter 130 of the second synthetic vitreous fiber sheet 114. The first cylinder edge 106 of the cylindrical first synthetic vitreous sheet 104, and the perimeter indicated by the arrow 130 of the second synthetic vitreous fiber sheet 114, may then be joined together to form the Fire Shroud 100. In another example, the first cylinder edge 106 of the cylindrical first synthetic vitreous sheet 104, and the perimeter indicated by the arrow 130 of the second synthetic vitreous fiber sheet 114, may be placed in position together as shown in FIG. 1 and an adhesive tape may be placed at a joint 132 between the cylindrical first synthetic vitreous fiber sheet 104 and the second synthetic vitreous fiber sheet 114. The adhesive tape may be placed at the joint 132 on the exterior 134 or within the interior 136 of the Fire Shroud 100. As a further example (not shown) the second synthetic vitreous fiber sheet 114 may have a perimeter indicated by the arrow 130 larger than a perimeter indicated by the arrow 138 of the cylindrical first synthetic vitreous fiber sheet 104. In that example, an adhesive composition or a double-sided adhesive tape may be placed near the first cylinder edge 106 or near the perimeter indicated by the arrow 130 of the second synthetic vitreous fiber sheet 114 or near both the first cylinder edge 106 and the perimeter 130 of the second sheet. The cylindrical first synthetic vitreous fiber sheet 104 and the second synthetic vitreous fiber sheet 114 may then be joined together. As additional examples (not shown), the cylindrical first synthetic vitreous fiber sheet 104 and the second synthetic vitreous fiber sheet 114 may be joined together by stitching, stapling, or other fasteners.

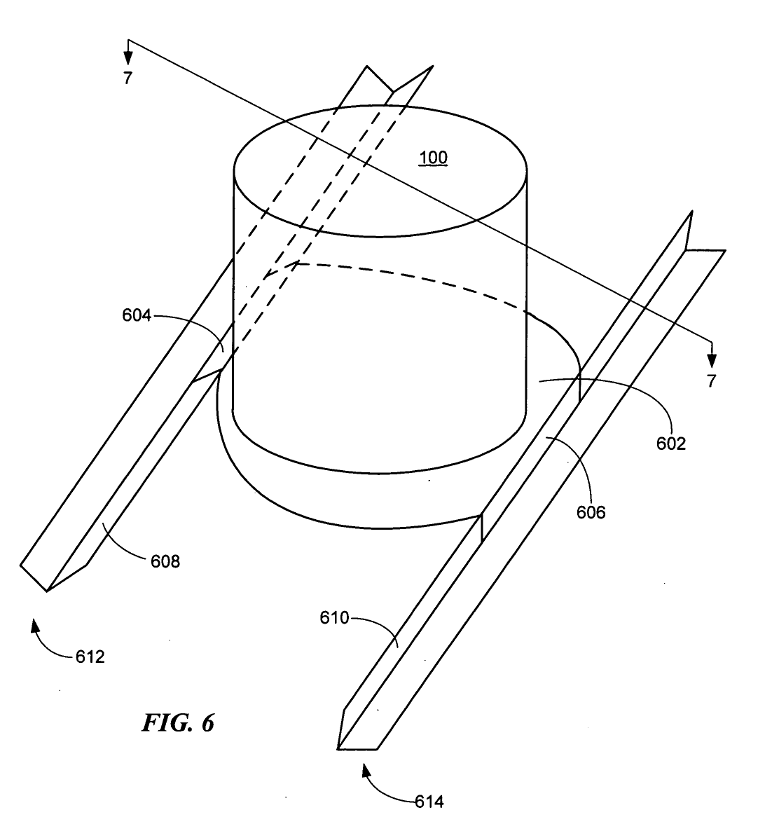

FIG. 5 is a perspective view showing the Fire Shroud 100 formed in FIG. 4, installed on a barrier surface-mountable loudspeaker 102. The cylindrical first synthetic vitreous sheet 104 and the second synthetic vitreous fiber sheet 114 may be joined together, forming the Fire Shroud 100. The Fire Shroud 100 may, as an example, include a cavity configured to the shape of and to contain the back-can 126 of the barrier surface-mountable loudspeaker 102. It is understood by those skilled in the art that throughout this specification the phrase “contain the back-can” means that a portion of the back-can 126 may be inserted into a cavity in the Fire Shroud 100. In examples, most, or nearly all, or all, of the back-can 126 may be so inserted into a cavity in the Fire Shroud 100. As an example, the Fire Shroud 100 may be sized to completely contain the back-can 126 of a barrier surface-mountable loudspeaker 102, leaving exposed only a sound-emission interface 140. As an example, the sound-emission interface 140 may include a grille face of a grille 142. In another example (not shown) a Fire Shroud 100 may be sized to partially or completely contain the back-can of an in-barrier lighting fixture, leaving exposed a light-emission interface.

The term “synthetic vitreous fiber” as used throughout this specification broadly means and includes wools and continuous glass filaments, as they are defined by the International Agency for Research on Cancer (“IARC”). Synthetic vitreous fibers are generally formed from inorganic materials derived from one or more sources including rock, slag, glass precursors such as sand, and clay. The compositions of synthetic vitreous fibers primarily include ingredients selected from silicon dioxide, aluminum oxide, calcium oxide, magnesium oxide, and iron oxide, and may as examples include other alkaline metal oxides, alkaline earth metal oxides, and other metal oxides. The term “wool” as used throughout this specification broadly means and includes mineral wool, glass wool, refractory ceramic fibers, and engineered bio-soluble fibers. The term “continuous glass filaments” as used throughout this specification broadly means and includes glass filaments formed from a molten composition derived from one or more sources including rock, slag, glass precursors such as sand, and clay that is extruded from a nozzle and continuously spun or drawn. As an example, continuous glass filaments may be made from a composition primarily including silicon dioxide, aluminum oxide, boron oxide, and calcium oxide. In an example, such a composition may be commercially referred to as “electrical glass” or “E-glass,” such as a borosilicate glass.

The term “mineral wool” as used throughout this specification includes slag wool and rock wool, the latter also referred to as stone wool. Rock wool is generally made from compositions including igneous rock such as basalt, diabase, olivine, or their mixtures. Slag wool is generally made from compositions including blast furnace slag. Glass wool is generally made from compositions including more than about 50% by weight silicon dioxide, and may as an example include silicon dioxide at a concentration within a range of between about 55% and about 70% by weight. Refractory ceramic fibers are generally made from compositions including kaolin, having high concentrations of both silicon dioxide and aluminum oxide.

The wools are generally formed from a molten composition by rotary or centrifugal spinning processes without extruding the molten composition through a nozzle. In an example, a wool may be made by melting a composition including inorganic materials derived from one or more sources including rock, slag, glass precursors such as sand, and clay, and blowing a stream of a gas such as air through the molten composition. The gas may include water, in the form of steam as an example. As a further example, the molten composition for forming the wool may then be centrifugally or radially spun onto a spinning wheel.

The absence of extrusion of a molten composition through a nozzle in methods for forming molten compositions into wools typically results in production of discontinuous fibers rather than continuous filaments. The resulting fibers typically have variable diameters. As an example, the diameters of rock wool fibers may vary within a range of between about 3 microns and about 7 microns. In another example, the diameters of glass wool fibers may vary within a range of between about 3 microns and about 15 microns. As a further example, the diameters of refractory ceramic fibers may vary within a range of between about 1 micron and about 5 microns. In contrast, the diameters of continuous glass filaments may, as an example, be controlled to a selected portion of a range, such as a selected portion of a range of between about 3 microns and about 25 microns.

The potential for fibers that are formed from any type of composition to be respirable and to then potentially cause diseases such as cancer is a general concern in fiber manufacture and utilization. Toxicity of fibers, including synthetic vitreous fibers, is partially dependent on their physical dimensions. In general, the greater the diameter and length of fibers, the lower is their typical airborne concentration and resultant potential toxicity. As an example, fibers having diameters of less than about 3 microns are considered by the IARC to be respirable. In general, wools accordingly may be more likely to contain respirable fibers than continuous glass filaments, as filaments tend to have substantially greater lengths and because the diameters of such filaments may be better controlled during manufacture than may be the diameters of discontinuous wool fibers. Since the diameters of some typical rock wool fibers and glass wool fibers may be as small as about 3 microns, some of such fibers may be respirable. In addition, since the lower end of a typical fiber diameter size range for refractory ceramic fibers may be about 1 micron, more of the fibers in refractory ceramic fiber wools may be respirable. In an example where a wool is selected as the source of synthetic vitreous fibers for making synthetic vitreous fiber sheets or a synthetic vitreous fiber body in fabricating a Fire Shroud 100, the type of wool that is selected may be a mineral wool or a glass wool. Utilization of refractory ceramic wools as the source of synthetic vitreous fibers for making synthetic vitreous fiber sheets or a body in fabricating a Fire Shroud 100 may, as an example, thus be avoided. As another example, continuous glass filaments may be selected as the source of synthetic vitreous fibers for making synthetic vitreous fiber sheets or a body for making a Fire Shroud 100. In an additional example, a diameter size range for the continuous glass filaments, including a controlled minimum diameter in excess of about 3 microns, may be selected. As a further example, synthetic vitreous fiber sheets or a body including continuous glass filaments or wool fibers having sampled diameters within a range of between about 6 microns and about 10 microns may be selected for making a Fire Shroud 100. Synthetic vitreous fiber diameter sampling for this purpose may include, as an example, determining the diameters of at least about one hundred selected fibers or filament sections.

Natural mineral fiber sources such as asbestos have uncontrolled, variable, fiber diameters and lengths. Accordingly, natural mineral fiber sources may include more respirable fibers having diameters of less than about 3 microns than may be included in synthetic vitreous fibers. In an example, the utilization of natural mineral fiber sources in fabrication of a Fire Shroud 100 may accordingly be avoided. However, it is understood by those skilled in the art that natural mineral fiber sources may be substituted for or combined with synthetic vitreous fibers in making a synthetic vitreous fiber body or in making synthetic vitreous fiber sheets selected for forming the cylindrical first synthetic vitreous fiber sheet 104 and the second synthetic vitreous fiber sheet 114 in fabrication of the Fire Shroud 100.

The rock, slag, glass precursors such as sand, and clay from which synthetic vitreous fibers are formed all are non-combustible. In addition, rock, slag, glass precursors such as sand, and clay all include metal elements. Such metal elements generally have significant molecular weights. Synthetic vitreous fibers accordingly have substantial mass densities and may function as non-combustible heat insulators. In addition, fabrication of synthetic vitreous fibers into a woven or non-woven sheet or body may trap air in interstices between the fibers. The trapped air itself adds to the non-combustibility and heat insulating capability of the woven or non-woven sheet or body. As an example, graphite fibers may be avoided as an alternative to synthetic vitreous fibers for making the Fire Shroud 100. Graphite fibers themselves are formed of elemental carbon, having a low molecular weight of only 6 grams per mole. Hence, graphite fibers alone may not provide sufficient mass density to insulate the barrier surface-mountable electromagnetic device from the heat of a fire, potentially leading to combustion within or passing through the barrier surface-mountable electromagnetic device.

In an example, synthetic vitreous fibers may be selected and formed into an intertwined mass such as a synthetic vitreous fiber sheet or body, as an integral part of the process for making the fibers themselves from molten materials. In this manner, the intertwined mass of synthetic vitreous fibers may be self-bonded without a need to add other materials or to undertake additional steps for bonding the intertwined fibers together. As a further example, the intertwined mass of synthetic vitreous fibers may include a combustible or non-combustible binder composition. A urea-extended phenol-formaldehyde binder having a Chemical Abstract Service designation of 25104-55-6 may, in an example, be utilized. In another example, an inorganic binder including kyanite, sodium silicate, calcined clay, crystalline silica, and water may be utilized.

The intertwined mass may, as an example, take the form of a flexible sheet. As examples, selected synthetic vitreous fibers may be formed into a woven or non-woven sheet having suitable dimensions for forming, or being cut down to size for forming, the cylindrical first synthetic vitreous fiber sheet 104 and the second synthetic vitreous fiber sheet 114 in fabrication of the Fire Shroud 100. Such woven or non-woven sheets for forming the cylindrical first synthetic vitreous fiber sheet 104 and the second synthetic vitreous fiber sheet 114 may, in an example, have thicknesses of at least about one inch. As another example, the woven or non-woven sheets for forming the cylindrical first synthetic vitreous fiber sheet 104 and the second synthetic vitreous fiber sheet 114 may have thicknesses within a range of between about one inch and about three inches. Synthetic vitreous fiber bodies may as an example have analogous thicknesses. An increased thickness of the sheets generally increases the fire protection provided by the Fire Shroud 100.

The intertwined mass may further, as an example (not shown), take the form of a rigid board. As another example (not shown), the cylindrical first synthetic vitreous fiber sheet 104 may be integrally formed as a seamless cylinder having a defined length, without a first sheet edge 116 or a second sheet edge 118. The defined length may, as an example, be sufficiently large so that a portion of the seamless cylinder may be cut to form a cylindrical first synthetic vitreous fiber sheet 104 sized to the shape of and to contain a portion of the back-can 126 of a selected barrier surface-mountable electromagnetic device. In another example (not shown), the cylindrical first synthetic vitreous fiber sheet 104 may be formed by assembly together of two half-cylinder synthetic vitreous fiber sheets each shaped as a half-cylinder having first and second sheet edges and a defined length. The two half-cylinder vitreous fiber sheets may, as an example, then be assembled together around the back-can 126 of a selected barrier surface-mountable electromagnetic device and joined together using an adhesive composition or a single- or double-sided adhesive tape in a manner analogous to the above discussion of techniques for joining synthetic vitreous fiber sheet edges together. In a further example (not shown), a cylindrical first synthetic vitreous fiber sheet 104 and a second synthetic vitreous fiber sheet 114 may be integrally formed as a cylindrical tube having an integral end-cap substituting for a second synthetic vitreous fiber sheet, collectively constituting a Fire Shroud 100 for assembly onto the back-can 126 of a barrier surface-mountable electromagnetic device. These examples of synthetic vitreous fiber sheets may, as an example, be selected to have a rigid structure.

It is understood by those skilled in the art that the examples of Fire Shrouds 100 discussed throughout this specification both in connection with and as shown in the drawings may be fabricated to include a synthetic vitreous fiber body utilizing first and second synthetic vitreous fiber sheets 104 and 114, or utilizing an integrally-formed cylindrical first synthetic vitreous fiber sheet or two half-cylinder synthetic vitreous fiber sheets instead of the cylindrical first synthetic vitreous fiber sheet, or by integrally forming a body including a cylindrical tube having an integrally-formed cap. It is further understood by those skilled in the art that Fire Shrouds 100 may further be fabricated by forming other synthetic vitreous fiber sheets or bodies that may be integrated to form a cylindrical tube having an integrally-formed cap.

In an example, synthetic vitreous fiber bodies, or sheets for forming the cylindrical first synthetic vitreous fiber sheet 104 and the second synthetic vitreous fiber sheet 114, may be selected that comply with Underwriters Laboratories (“UL”) 723 “Standard for Test for Surface Burning Characteristics of Building Materials”, which itself references UL 263 “Standard for Fire Tests of Building Construction and Materials”. UL 723 is also published as ASTM International (“ASTM”) E84 “Standard Test Method for Surface Burning Characteristics of Building Materials.” As a further example, synthetic vitreous fiber bodies, or sheets for forming the first and second synthetic vitreous fiber sheets 104 and 114, may be selected that comply with UL 2043 “Standard for Fire Test for Heat and Visible Smoke Release for Discrete Products and Their Accessories Installed in Air-Handling Spaces”. In another example, synthetic vitreous fiber bodies, or sheets for forming the first and second synthetic vitreous fiber sheets 104 and 114, may be selected that comply with National Fire Protection Association (“FPA”) Standard 255 “Standard Method of Test of Surface Burning Characteristics of Building Materials.” In an additional example, synthetic vitreous fiber bodies, or sheets for forming the first and second synthetic vitreous fiber sheets 104 and 114, may be selected that comply with Underwriters Laboratories of Canada (“ULC”) S102-03 “Surface Burning Characteristics of Building Materials and Assemblies” superseding ULC Standard S102-88.

As another example, an FBX COREPLUS 1200® industrial flexible batt insulation having a grade designation of 1210, 1212, 1240, 1260, or 1280 and manufactured from a composition including basalt mineral fibers may be utilized for forming a synthetic vitreous fiber body or the cylindrical first synthetic vitreous fiber sheet 104 and the second synthetic vitreous fiber sheet 114. FBX COREPLUS 1200® industrial flexible batt insulation is commercially available from Fibrex Insulations Inc., P.O. Box 2079, 561 Scott Rd., Samia, Ontario, Canada N7T 7L4; www.fibrex.org. FBX COREPLUS 1200® industrial flexible batt insulation may comply with UL 723, UL 263, and ULC S102-03. As another example, an FBX COREPLUS 1200® pipe insulation having a grade designation of 1210, 1212, 1240, 1260, or 1280, and manufactured from a composition including basalt mineral fibers may be utilized for forming a cylindrical synthetic vitreous fiber body or a cylindrical first synthetic vitreous fiber sheet 104.

Commercially-available synthetic vitreous fiber bodies and sheets may include additional ingredients such as an oil added to prevent fibers from falling off or “dusting off” of the bodies or sheets. In an example, commercially available materials for forming the bodies or first and second synthetic vitreous fiber sheets that do not include dust-controlling oils or other additives may be selected, to avoid non-compliance with applicable standards by UL, ULC, ASTM, NFPA, building codes, or other fire-resistance and smoke-reduction standards. It is understood by those skilled in the art that a binder may nevertheless be needed to maintain the integrity of a synthetic vitreous fiber body or sheet.

As an example, an adhesive composition to be utilized for making the Fire Shroud 100 as discussed above may be selected based on factors including resistance of the adhesive composition to combustion, retention of joint integrity at high temperatures, production of minimal smoke, release of minimal toxic materials upon decomposition, and initial bonding effectiveness of the adhesive to the selected synthetic vitreous fiber bodies or sheets. The adhesive composition may, as an example, include a flame retardant. In an example, the adhesive composition may include a thermosetting polymeric resin so that the adhesive may not melt even upon exposure to extreme heat. Examples of thermosetting adhesive compositions include urea-formaldehyde, resorcinol-formaldehyde, melamine-formaldehyde, and one-component epoxides. As another example, a refractory cement may be utilized. A refractory cement may include ceramic fibers and an inorganic binder. In an example, Fiberstick™ refractory cement, including kyanite, sodium silicate, calcined clay, crystalline silica, and water may be utilized. Fiberstick™ refractory cement is commercially available from Unifax Corporation, 2351 Whirlpool St., Niagara Falls, N.Y. 14305; www.unifrax.com.

In another example, a tape web including a single-sided or double-sided adhesive coating may be selected based on the same factors as discussed above with regard to adhesive compositions. Since the tape web may provide structural strength to a joint but not itself bond to a synthetic vitreous fiber body or sheet, the tape web may be made of a selected material that is more fire-resistant than the adhesive may be. As examples, the tape web itself may be formed from a composition selected from the materials utilized for forming the synthetic vitreous fiber body or sheets, as discussed above. The adhesive composition coating included on either or both surfaces of the tape web may be selected as discussed in the preceding paragraph. In an example, Silicaflex™ Tape AB, including a silicon dioxide fiber web coated on one side with a pressure sensitive adhesive, may be utilized. Silicaflex™ Tape AB is commercially available from ADL Insulflex, Inc., 8783 Dale Rd., Cobourg, Ontario, Canada K9A 4J9; www.adlinsulflex.com.

Following completion of assembly, the Fire Shroud 100 may as an example be slid onto a portion of the back-can 126 of a selected barrier surface-mountable loudspeaker 102 in the direction of the arrow 144, as shown in FIG. 1. In an example, the Fire Shroud 100 may be compatibly sized and shaped for the back-can 126, so that the Fire Shroud 100 may snugly fit over and contain a portion of the back-can 126. The Fire Shroud 100 may, as an example, be manufactured in a series of graduated sizes standardized for a product line of barrier surface-mountable loudspeakers 102. In another example, the Fire Shroud 100 may be manufactured in a series of graduated sizes having the following interior cavity depths in the directions of the arrow 144 and the following interior cavity diameters in the directions of the arrow 146:8.3 inch depth and 9.9 inch diameter; 13.6 inch depth and 13.6 inch diameter; 7.9 inch depth and 7.7 inch diameter; and 4.2 inch depth and 7.7 inch diameter. As a further example, the Fire Shroud 100 may be sized to the shape of and to completely contain the back-can 126 of the barrier surface-mountable loudspeaker 102, leaving exposed only a grille face 140 for projecting sound from a grille 142. Barrier surface-mountable loudspeakers 102 may, as an example, include a bracket (not shown) at the end of the back-can 126 for pendulum-mounting the barrier surface-mountable loudspeaker 102 or for attaching a seismic protection cable. In an example, no provision may be made in the Fire Shroud 100 for utilization of such a bracket, as an aperture would be needed in the second synthetic vitreous fiber sheet 114, compromising the fire barrier.

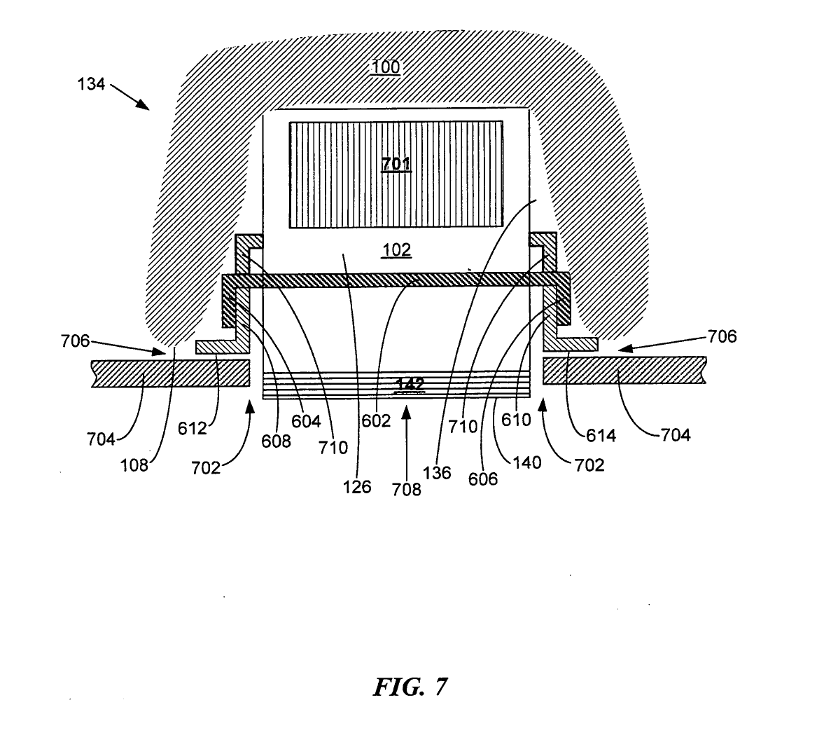

FIG. 6 is a perspective view showing an example of the Fire Shroud 100 of FIG. 1 installed on a barrier surface-mountable loudspeaker 102. FIG. 7 is a cross-sectional side view taken on line 7-7 of an example of a Fire Shroud 100 of FIG. 6 installed on the barrier surface-mountable loudspeaker 102 mounted on ceiling rails integrated with a suspended ceiling tile grid frame. The Fire Shroud 100 may, as an example, include a cavity conforming to the shape of and containing a portion of the back-can 126 of the barrier surface-mountable loudspeaker 102. The back-can 126 may, as an example, include a sound-producing element 701. Generally, a variety of sound-producing elements 701 typically associated with loudspeakers 102 are known to persons skilled in the art, and therefore need not be described in detail for an understanding of the subject matter being described in this disclosure. Non-limiting examples of sound-producing elements 701 may include electromagnetic drivers, magnets, pole pieces, voice coils, wave guides, diaphragms, combinations of one or more of the foregoing, and the like. In an example, the barrier surface-mountable loudspeaker 102 may be mounted on a c-bracket 602. The c-bracket 602 may include downwardly directed tabs 604 and 606 positioned to overlay upwardly directed tabs 608 and 610 of ceiling rails 612 and 614. The ceiling rails 612 and 614 may act as a bridge between framing members (not shown) of a suspended ceiling tile grid frame (not shown). The c-bracket 602 and ceiling rails 612 and 614 may collectively suspend the barrier surface-mountable loudspeaker 102 in an aperture 702 of a ceiling tile 704. The Fire Shroud 100 may, as an example, snugly fit over a portion of the back-can 126 and the c-bracket 602. The Fire Shroud 100 may, in an example, leave a gap 706 of less than about one-eighth of an inch between the second cylinder edge 108 and the ceiling tile 704. In an example, a sound-emission interface 140 of the barrier surface-mountable loudspeaker 102 may be exposed at a barrier surface 708. As an example, the sound-emission interface 140 may include a grille face of a grille 142

The Fire Shroud 100 may be attached to the barrier surface-mountable loudspeaker 102, as examples, by an adhesive composition or an adhesive tape applied to the Fire Shroud 100 and the barrier surface-mountable loudspeaker 102. As a further example, the barrier surface-mountable loudspeaker 102 may include mounting tabs 710 configured to swing laterally away from the back-can 126 and to support weight of the barrier surface-mountable loudspeaker 102 on the c-bracket 602. The Fire Shroud 100 may, as an example (not shown), be secured in place on the barrier surface-mountable loudspeaker 102 by pinching the second cylinder edge 108 of the Fire Shroud 100 between the c-bracket 602 and the mounting tabs 710. In an additional example (not shown), the Fire Shroud 100 may be secured in place on the barrier surface-mountable loudspeaker 102 by pinching the second cylinder edge 108 of the Fire Shroud 100 between the downwardly directed tabs 604 and 606 of the c-bracket 602 and the upwardly directed tabs 608 and 610 of the ceiling rails 612 and 614. As another example (not shown), a plurality of clips may be attached to the second cylinder edge 108 of the Fire Shroud 100 and to one or more of the following: mounting tabs 710, c-bracket 602, and ceiling rails 612 and 614.

The Fire Shroud 100 may, as an example, be utilized to provide fire resistance to an electromagnetic device such as a barrier surface-mountable loudspeaker 102 installed in a ceiling formed by sheet rock or a substitute for sheet rock, or installed in a suspended ceiling including a tile grid frame. The Fire Shroud 100 may further, as examples, be utilized to provide fire resistance to an electromagnetic device such as a barrier surface-mountable loudspeaker 102 installed in another building interior surface such as a wall or floor.

Although the invention has been described with reference to a particular example of an embodiment, it will be apparent to those skilled in the art that various changes and modifications may be made without departing from the spirit and scope of the invention. Such changes and modification are intended to be covered by the appended claims.

What is claimed is:

1. A fire-resistant shroud (“Fire Shroud”) for a barrier surface-mountable electromagnetic device, comprising a synthetic vitreous fiber body having a cavity configured to the shape of a portion of the electromagnetic device.

2. The fire-resistant shroud of claim 1, where the electromagnetic device is a barrier surface-mountable loudspeaker, the synthetic vitreous fiber body having a cavity configured to the shape of a barrier surface-mountable loudspeaker back-can.

3. The fire-resistant shroud of claim 1, where the synthetic vitreous fiber body includes a first synthetic vitreous fiber sheet in the form of a cylinder, the cylinder having first and second cylinder edges respectively defining first and second cylinder ends, and a second synthetic vitreous fiber sheet joined with the first cylinder edge and closing the first cylinder end.

4. The fire-resistant shroud of claim 3, where the first synthetic vitreous fiber sheet includes two sheet edges joined together to form the cylinder.

5. The fire-resistant shroud of claim 1, where the synthetic vitreous fiber body includes two half-cylinder synthetic vitreous fiber sheets each shaped as a half-cylinder, the two half-cylinders joined together forming a cylinder, the cylinder having first and second cylinder edges respectively defining first and second cylinder ends, and a second synthetic vitreous fiber sheet joined with the first cylinder edge and closing the first cylinder end.

6. The fire-resistant shroud of claim 1, where the synthetic vitreous fiber body includes an integral synthetic vitreous fiber cylinder, the cylinder having first and second cylinder edges respectively defining first and second cylinder ends, and the synthetic vitreous fiber body includes a second synthetic vitreous fiber sheet joined with the first cylinder edge and closing the first cylinder end.

7. The fire-resistant shroud of claim 1, where the synthetic vitreous fiber body includes an integral synthetic vitreous fiber cylinder having an end-cap.

8. A barrier surface-mountable loudspeaker system, comprising:
a barrier surface-mountable loudspeaker having a back-can including a sound-producing element; and
a synthetic vitreous fiber body having a cavity configured to the shape of a barrier surface-mountable loudspeaker back-can.

9. The barrier surface-mountable loudspeaker system of claim 8, where the synthetic vitreous fiber body includes a first synthetic vitreous fiber sheet in the form of a cylinder, the cylinder having first and second cylinder edges respectively defining first and second cylinder ends, and a second synthetic vitreous fiber sheet joined with the first cylinder edge and closing the first cylinder end.

10. The barrier surface-mountable loudspeaker system of claim 9, where the first synthetic vitreous fiber sheet includes two sheet edges joined together to form the cylinder.

11. The barrier surface-mountable loudspeaker system of claim 8, where the synthetic vitreous fiber body includes two half-cylinder synthetic vitreous fiber sheets each shaped as a half-cylinder, the two half-cylinders joined together forming a cylinder, the cylinder having first and second cylinder edges respectively defining first and second cylinder ends, and a second synthetic vitreous fiber sheet joined with the first cylinder edge and closing the first cylinder end.

12. The barrier surface-mountable loudspeaker system of claim 8, where the synthetic vitreous fiber body includes an integral synthetic vitreous fiber cylinder, the cylinder having first and second cylinder edges respectively defining first and second cylinder ends, and the synthetic vitreous fiber body includes a second synthetic vitreous fiber sheet joined with the first cylinder edge and closing the first cylinder end.

13. The barrier surface-mountable loudspeaker system of claim 8, where the synthetic vitreous fiber body includes an integral synthetic vitreous fiber cylinder having an end-cap.

14. A method of installing a barrier surface-mountable electromagnetic device in a barrier surface of an interior space, comprising:
securing an electromagnetic device in an operable position with a portion of the electromagnetic device within a barrier surface; and
installing a fire resistant shroud to contain the portion of the electromagnetic device, the fire resistant shroud including a synthetic vitreous fiber body having a cavity configured to the shape of the portion of the electromagnetic device.

15. The method of claim 14, where the electromagnetic device is a barrier surface-mountable loudspeaker, the synthetic vitreous fiber body having a cavity configured to the shape of a portion of a barrier surface-mountable loudspeaker back-can.

16. The method of claim 14, where the synthetic vitreous fiber body includes a first synthetic vitreous fiber sheet in the form of a cylinder, the cylinder having first and second cylinder edges respectively defining first and second cylinder ends, and a second synthetic vitreous fiber sheet joined with the first cylinder edge and closing the first cylinder end.

17. The method of claim 16, where the first synthetic vitreous fiber sheet includes two sheet edges joined together to form the cylinder.

18. The method of claim 14, where the synthetic vitreous fiber body includes two half-cylinder synthetic vitreous fiber sheets each shaped as a half-cylinder, the two half-cylinders joined together forming a cylinder, the cylinder having first and second cylinder edges respectively defining first and second cylinder ends, and a second synthetic vitreous fiber sheet joined with the first cylinder edge and closing the first cylinder end.

19. The method of claim 14, where the synthetic vitreous fiber body includes an integral synthetic vitreous fiber cylinder, the cylinder having first and second cylinder edges respectively defining first and second cylinder ends, and a second synthetic vitreous fiber sheet joined with the first cylinder edge and closing the first cylinder end.

20. The method of claim 14, where the synthetic vitreous fiber body includes an integral synthetic vitreous fiber cylinder having an end-cap.
